(19) United States
(12) Patent Application Publication
(10) Pub. No.: US 2016/0126119 A1
(43) Pub. Date: May 5, 2016

(54) LASER ANNEALING APPARATUS

(71) Applicant: SAMSUNG ELECTRONICS CO., LTD., Suwon-si (KR)

(72) Inventors: Joonghan SHIN, Yongin-si (KR); Bongjin KUH, Suwon-si (KR); Wanit MANOROTKUL, Hwaseong-si (KR); Hanmei CHOI, Seoul (KR)

(21) Appl. No.: 14/881,414

(22) Filed: Oct. 13, 2015

(30) Foreign Application Priority Data
Nov. 5, 2014 (KR) 10-2014-0153079

(51) Int. Cl. H01L 21/67; H01L 21/683; H01L 21/324; B23K 26/00; H01L 21/687

(52) U.S. Cl. CPC H01L 21/67115; B23K 26/00; H01L 21/687; H01L 21/67109; H01L 21/324; H01L 21/6831

(57) ABSTRACT

A laser annealing apparatus includes a process chamber with a chamber window to transmit a laser beam, and a chuck in the process chamber, a top surface of the chuck supporting a loaded substrate, and a width of the chuck being smaller than a width of the loaded substrate.

### CROSS-REFERENCE TO RELATED APPLICATION

Korean Patent Application No. 10-2014-0153079, filed on Nov. 5, 2014, in the Korean Intellectual Property Office, and entitled: “Laser Annealing Apparatus,” is incorporated by reference herein in its entirety.

### BACKGROUND

1. Field

Embodiments relate to a semiconductor manufacture apparatus. More particularly, embodiments relate to a laser annealing apparatus.

2. Description of the Related Art

Semiconductor devices are widely used in an electronic industry because of their small sizes, multi-functional characteristics, and/or low manufacture costs. The semiconductor devices may be manufactured by various semiconductor processes, e.g., photolithography processes, etching processes, deposition processes, annealing processes, and ion implantation processes. The semiconductor processes may be performed using semiconductor manufacture apparatuses. The semiconductor manufacture apparatuses are being developed to minimize or prevent various defects of the semiconductor processes and to improve process margins of the semiconductor processes.

### SUMMARY

Embodiments provide laser annealing apparatuses capable of improving reliability of a laser annealing process.

Embodiments also provide laser annealing apparatuses capable of minimizing or preventing contamination.

In one aspect, a laser annealing apparatus may include a process chamber having a chamber window to transmit a laser beam, and a chuck in the process chamber, a top surface of the chuck supporting a loaded substrate, and a width of the chuck being smaller than a width of the loaded substrate.

In some embodiments, a bottom surface of an edge portion of the substrate loaded on the chuck may be exposed.

In some embodiments, an area of the loaded substrate may be greater than an area of the top surface of the chuck, and the chuck may be completely covered by the loaded substrate.

In some embodiments, the width of the chuck may be equal to or greater than 80% of the width of the loaded substrate.

In some embodiments, the laser annealing apparatus may further include: a laser source generating the laser beam. The process chamber may further include: a bottom portion on which the chuck is disposed, and a wall portion extending upward from an edge of the bottom portion. The chamber window may close a top end of an inner space surrounded by the bottom portion and the wall portion, and the laser beam may be irradiated to the loaded substrate through the chamber window.

In some embodiments, the laser annealing apparatus may further include: a protection plate disposed on the bottom portion of the process chamber. The protection plate may be formed of a material of which a melting point is higher than that of the bottom portion of the process chamber. The bottom portion of the process chamber may include: an overlap portion vertically overlapping with the loaded substrate, and a non-overlap portion not vertically overlapping with the loaded substrate. At least a portion of the protection plate may be disposed on the non-overlap portion adjacent to the overlap portion.

In some embodiments, the laser annealing apparatus may further include: a chuck supporter disposed under the chuck and supporting the chuck. A width of the chuck supporter may be smaller than the width of the chuck, and the protection plate may have a ring shape that surrounds the chuck supporter when viewed from a plan view.

In some embodiments, a portion of an outer sidewall of the protection plate may be concave toward an inner sidewall of the protection plate.

In some embodiments, a cooling channel through which a coolant flows may be provided within the bottom portion of the process chamber.

In some embodiments, at least a portion of the cooling channel may vertically overlap with the non-overlap portion of the bottom portion of the process chamber.

In some embodiments, the laser annealing apparatus may further include: a cooling plate disposed under the bottom portion of the process chamber.

In some embodiments, the cooling plate may include a cooling channel through which a coolant flows. The bottom portion of the process chamber may include: an overlap portion vertically overlapping with the loaded substrate, and a non-overlap portion not vertically overlapping with the loaded substrate. At least a portion of the cooling plate may vertically overlap with the non-overlap portion adjacent to the overlap portion.

In some embodiments, the laser annealing apparatus may further include: a stage on which the process chamber is disposed, and a chamber supporter disposed between the process chamber and the stage. The process chamber and the chamber supporter may be two-dimensionally movable on the stage.

In some embodiments, the chuck may have a heater to control temperature of the loaded substrate.

In another aspect, a laser annealing apparatus may include a process chamber including a bottom portion, a wall portion extending upward from an edge of the bottom portion, and a chamber window closing a top end of an inner space surrounded by the bottom portion and the wall portion, a chuck disposed on the bottom portion of the process chamber, the chuck having a top surface on which a substrate is loaded, and a laser source generating a laser beam, the laser beam configured to be irradiated to the loaded substrate through the chamber window. A width of the chuck may be smaller than a width of the loaded substrate, and a bottom surface of an edge portion of the substrate loaded on the chuck may be exposed.

In some embodiments, the width of the chuck may be equal to or greater than 80% of the width of the loaded substrate.

In some embodiments, the laser annealing apparatus may further include: a protection plate disposed on the bottom portion of the process chamber. The protection plate may be formed of a material of which a melting point is higher than that of the bottom portion of the process chamber. At least a portion of the protection plate may not vertically overlap with the loaded substrate. A portion of the laser beam may be irradiated to the at least a portion of the protection plate when the laser beam is irradiated to the edge portion of the loaded substrate.

In some embodiments, a cooling channel through which a coolant flows may be formed within the bottom portion of the process chamber.

In some embodiments, the laser annealing apparatus may further include a cooling plate being in contact with a bottom surface of the bottom portion of the process chamber.

In yet another aspect, laser annealing apparatus may include a process chamber including a chamber window to transmit a laser beam, a chuck on a bottom of the process chamber, and a compensation plate contacting the bottom of the process chamber and having an outermost edge adjacent to a sidewall of the process chamber, at least a portion of the compensation plate overlapping the chuck.

In some embodiments, the compensation plate may be a protection plate having a melting point higher than that of the bottom of the process chamber.

In some embodiments, the protection plate may be between the bottom of the process chamber and the chuck, the protection plate extending along an entire perimeter of the chuck and having an outermost edge closer to the sidewall of the process chamber than to an outermost edge of the chuck.

In some embodiments, the compensation plate may include a cooling channel within the bottom of the process chamber.

In some embodiments, the compensation plate may include a cooling channel under the bottom of the process chamber, the bottom of the process chamber being between the cooling channel and the chuck.

In still another aspect, a laser annealing apparatus may include a process chamber including a chamber window, a chuck disposed in the process chamber and having a top surface on which a substrate is loaded, and a laser source generating a laser beam that is irradiated to the loaded substrate through the chamber window. An area of the loaded substrate may be greater than an area of the top surface of the chuck. The chuck may be completely covered by the loaded substrate, and a bottom surface of an edge portion of the substrate loaded on the chuck may be exposed.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic cross-sectional view of a laser annealing apparatus according to some embodiments;

FIG. 2 illustrates an enlarged view of a loaded substrate and a chuck of the laser annealing apparatus illustrated in FIG. 1;

FIG. 3 illustrates a plan view of the loaded substrate and the chuck of the laser annealing apparatus illustrated in FIG. 1;

FIG. 4 illustrates an enlarged view of a portion of a lift pin and a portion of the chuck of the laser annealing apparatus illustrated in FIG. 1;

FIG. 5 illustrates a plan view of a protection plate of the laser annealing apparatus illustrated in FIG. 1;

FIG. 6 illustrates a perspective view of the protection plate of the laser annealing apparatus illustrated in FIG. 1;

FIGS. 7 and 8 illustrate cross-sectional views of a method of operating the laser annealing apparatus illustrated in FIG. 1;

FIG. 9 illustrates a cross-sectional view of a laser annealing apparatus according to other embodiments; and

FIG. 10 illustrates a cross-sectional view of a laser annealing apparatus according to still other embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

The terminology used herein is for the purpose of describing particular embodiments only and is not intended to limit. As used herein, the singular terms “a,” “an” and “the” are intended to include the plural forms as well, unless the context clearly indicates otherwise. As used herein, the term “and/or” includes any and all combinations of one or more of the associated listed items.

In the drawing figures, the dimensions of layers and regions may be exaggerated for clarity of illustration. It will also be understood that when an element is referred to as being “connected” or “coupled” to another element, it may be directly connected or coupled to the other element or intervening elements may be present. Similarly, it will be understood that when an element, e.g., a layer, region or substrate, is referred to as being “on” another element, it can be directly on the other element or intervening elements may be present. In contrast, the term “directly” means that there are no intervening elements.

It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiments in the detailed description will be described with sectional views as ideal exemplary views. Accordingly, shapes of the exemplary views may be modified according to manufacturing techniques and/or allowable errors. Therefore, the embodiments are not limited to the specific shapes illustrated in the exemplary views, but may include other shapes that may be created according to manufacturing processes. Areas exemplified in the drawings have general properties, and are used to illustrate specific shapes of elements. Thus, this should not be construed as limited to the scope of the embodiments.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments explained and illustrated herein include their complementary counterparts. The same reference numerals or the same reference designators denote the same elements throughout the specification.

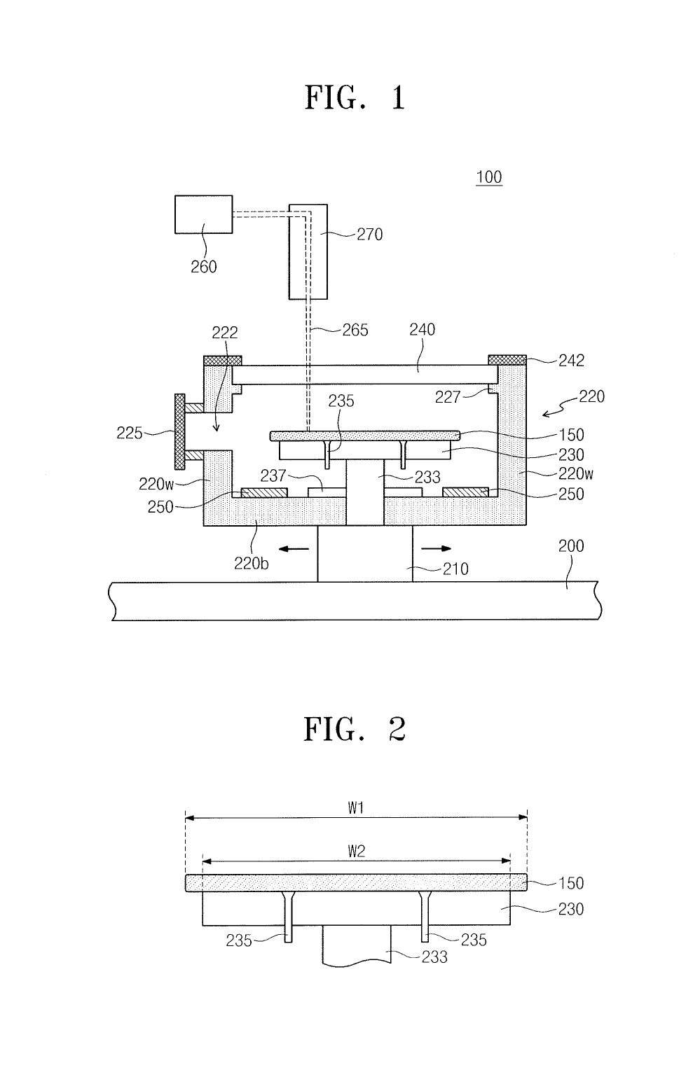

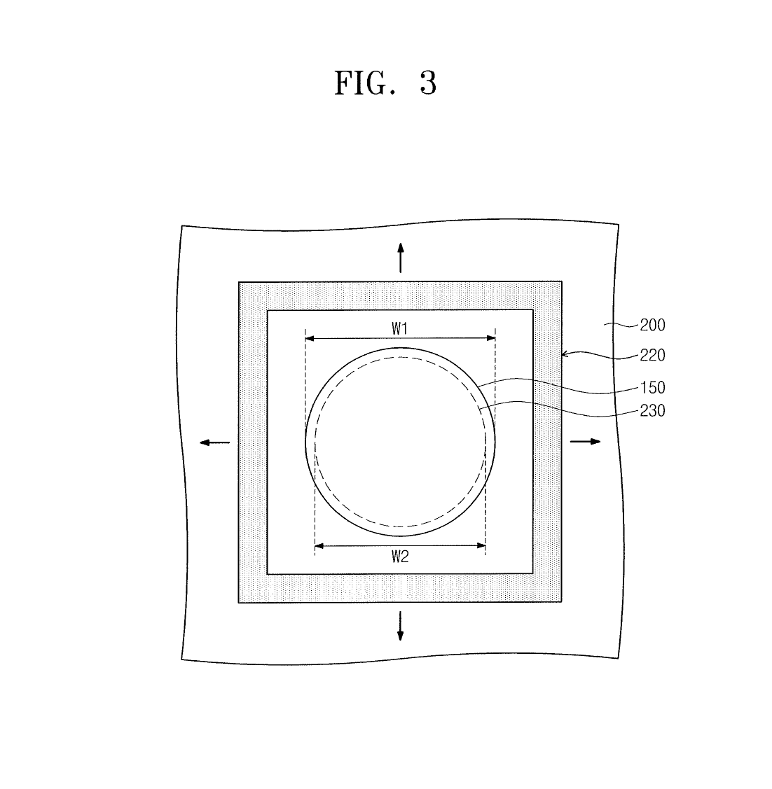

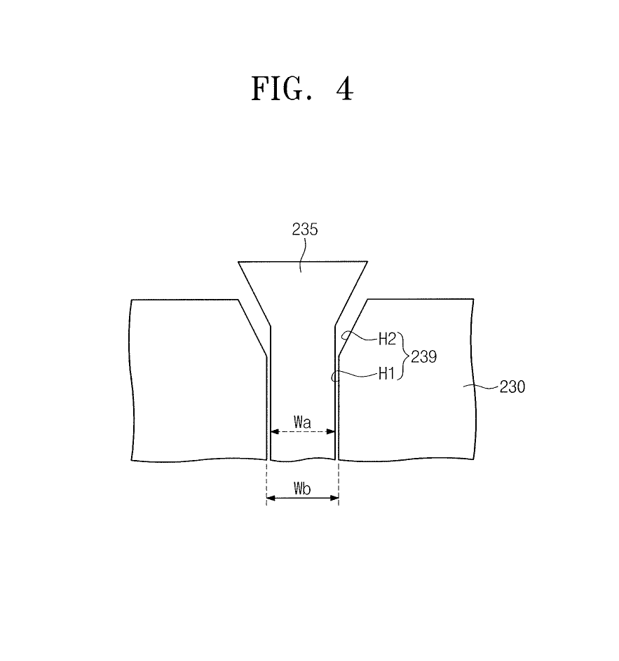

FIG. 1 illustrates a cross-sectional view of a laser annealing apparatus according to some embodiments. FIG. 2 illustrates an enlarged view of a loaded substrate and a chuck of the laser annealing apparatus illustrated in FIG. 1. FIG. 3 illustrates a plan view of the loaded substrate and the chuck of the laser annealing apparatus illustrated in FIG. 1. FIG. 4 illustrates an enlarged view of a portion of a lift pin and a portion of the chuck of the laser annealing apparatus illustrated in FIG. 1.

Referring to FIG. 1, a laser annealing apparatus 100 according to some embodiments may include a process chamber 220 having an inner space in which a laser annealing process is performed. In an embodiment, the process chamber 220 may include a bottom portion 220b and a wall portion 220w extending upward from an edge of the bottom portion 220b. The inner space of the process chamber 220 may be surrounded by the bottom portion 220b and the wall portion 220w.

A chuck 230 may be disposed on the bottom portion 220b in the inner space of the process chamber 220. The chuck 230 may have a top surface on which a substrate 150 is loaded. For example, the substrate 150 may be a semiconductor wafer including at least one of silicon, germanium, or a compound semiconductor. However, embodiments are not limited thereto. In another embodiment, the substrate 150 may be another substrate, e.g., a printed circuit board. For example, the chuck 230 may be an electrostatic chuck that fixes the loaded substrate 150 by electrostatic force. In another example, the chuck 230 may be a vacuum chuck that fixes the loaded substrate 150 by a vacuum pressure.

In some embodiments, the laser annealing process may be performed using a laser beam 265. The laser annealing apparatus 100 may further include a laser source 260 generating the laser beam 265. In addition, the laser annealing apparatus 100 may further include a beam delivery optic structure 270 that is used to transmit the laser beam 265 to a top surface of the loaded substrate 150. In other words, the laser beam 265 generated by the laser source 260 may be irradiated toward the loaded substrate 150 through the beam delivery optic structure 270.

The process chamber 220 may further include a chamber window 240 closing a top end of the inner space. The chamber window 240 may be formed of a material capable of transmitting the laser beam 265. The laser beam 265 transmitted through the beam delivery optic structure 270 may pass through the chamber window 240 so as to be irradiated to the loaded substrate 150. For example, the chamber window 240 may be formed of quartz that transmits a laser beam of a green wavelength range or a wavelength range shorter than the green wavelength range.

In an embodiment, a protrusion 227 may laterally protrude from an upper portion of an inner sidewall of the wall portion 220w. An edge of the chamber window 240 may be set on the protrusion 227. In other words, the chamber window 240 may be fixed on and supported by the protrusion 227, and may be upwardly spaced apart from the loaded substrate 150 and the chuck 230. In an embodiment, a fixing member 242 may be installed on a top surface of the wall portion 220w and a top surface of the edge of the chamber window 240. The chamber window 240 may be fixed by the protrusion 227 and the fixing member 242.

Referring to FIGS. 1 and 2, a width W2 of the chuck 230 is smaller than a width W1 of the loaded substrate 150. Thus, a bottom surface of an edge portion of the substrate 150 loaded on the chuck 230 may be exposed, e.g., an edge portion of the substrate 150 may extend beyond the chuck 230. In an embodiment, an area of the substrate 150 may be greater than an area of the top surface of the chuck 230, so the chuck 230 may be completely covered by the loaded substrate 150. As a result, it is possible to prevent the chuck 230 from being damaged by the laser beam 265 during the laser annealing process. This will be described later in more detail.

In an embodiment, the chuck 230 may have a heater function that controls a temperature of the loaded substrate 150. In other words, the chuck 230 may include a heater and a cooling system therein. The temperature of the loaded substrate 150 may be controlled or adjusted by the heater and the cooling system which are disposed within the chuck 230. In an embodiment, the width W2 of the chuck 230 may be smaller than 100% of the width W1 of the loaded substrate 150 and equal to or greater than 80% of the width W1 of the loaded substrate 150, e.g., the width W2 of the chuck 230 may be smaller than 100% of the width W1 of the loaded substrate 150 and equal to or greater than 90% of the width W1 of the loaded substrate 150. Thus, the chuck 230 may uniformly heat the edge portion of the loaded substrate 150 which is not in direct contact with the chuck 230, e.g., the size of the chuck 230 may be sufficient to uniformly heat the edge portion of the loaded substrate 150 that extends beyond the chuck 230.

Referring to FIG. 1, in an embodiment, the chuck 230 may be disposed on a chuck supporter 233. The chuck supporter 233 may have a pillar shape, e.g., a cylindrical shape. A width of the chuck supporter 233 may be smaller than the width W2 of the chuck 230, so the chuck supporter 233 may be completely covered by the chuck 230.

Referring to FIGS. 1-2 and 4, lift pins 235 may penetrate the chuck 230. The lift pin 235 may be used when the substrate 150 is loaded and unloaded. A length of the lift pin 235 may be greater than a thickness of the chuck 230, so a portion of the lift pin 235 may protrude from the chuck 230. As illustrated in FIG. 4, the lift pin 235 may include a pillar portion having a uniform width and a head portion disposed on the pillar portion. A width of the head portion may become progressively greater from a bottom end of the head portion toward a top end of the head portion. For example, the lift pin 235 may have a nail shape. The chuck 230 may include a through-hole 239 corresponding to the lift pin 235. The through-hole 239 may include a first region H1 corresponding to the pillar portion of the lift pin 235 and a second region H2 corresponding to the head portion of the lift pin 235. In other words, an inner sidewall of the first region H1 may be substantially perpendicular to the top surface of the chuck 230, and an inner sidewall of the second region H2 may be inclined with respect to the top surface of the chuck 230. In an embodiment, a width Wb of the first region H1 may be greater than a width Wa of the pillar portion of the lift pin 235. Here, the width Wb of the first region H1 is smaller than a width of the top end of the head portion of the lift pin 235. Thus, the lift pin 235 may be smoothly moved through the through-hole 239 in up and down directions but may not completely escape from the through-hole 239. In other words, when the lift pin 235 is moved downward through the through-hole 239, the head portion of the lift pin 235 may be supported by a top end of the first region H1 of the through-hole 239. When the head portion of the lift pin 235 is completely located in the second region H2 of the through-hole 239, a top surface of the lift pin 235 may be disposed at the same level or a lower level than the top surface of the chuck 230. Thus, the loaded substrate 150 may come in, e.g., direct, contact with the top surface of the chuck 230.

Referring to FIG. 1, a lift plate 237 may be disposed under the lift pins 235. The lift plate 237 may surround a sidewall of the chuck supporter 233 when viewed from a plan view. In other words, the chuck supporter 233 may penetrate, e.g., through an opening in the center of, the lift plate 237. The lift plate may be moved along the sidewall of the chuck supporter 233 in up and down directions. The lift pins 235 and the lift plate 237 will be described later in more detail.

A substrate path 222 may penetrate a portion of the wall portion 220w of the process chamber 220, and a door unit 225 may close or open the substrate path 222. The substrate 150 may be transferred into or transferred from the process chamber 220 through the substrate path 222. Even though not shown in the drawings, a load lock chamber may be connected to the door unit 225.

In an embodiment, the process chamber 220 may be disposed on a chamber supporter 210. The chamber supporter 210 may be disposed on a stage 200. The process chamber 220 may be fixed to the chamber supporter 210, and the process chamber 220 and the chamber supporter 210 may be two-dimensionally moved on the stage 200. As illustrated in FIG. 3, the process chamber 220 may be two-dimensionally moved on the stage 200 when viewed from a plan view. For example, the stage 200 may include rails, and the chamber supporter 210 may be two-dimensionally moved along the rails, e.g., along the directions indicated by the arrows in FIG. 3.

The chuck supporter 233 may penetrate the bottom portion 220b of the process chamber 220 so as to be connected to the chamber supporter 210. The chuck supporter 233 may protrude from the top surface of the bottom portion 220b.

Referring to FIG. 3, the substrate 150 may have, e.g., a circular shape when viewed from a plan view. In addition, the chuck 230 may have, e.g., a circular shape when viewed from a plan view. In this case, the width W1 of the substrate 150 may correspond to a diameter of the substrate 150, and the width W2 of the chuck 230 may correspond to a diameter of the chuck 230. However, embodiments are not limited thereto. The substrate 150 and the chuck 230 may have other shapes different from the circular shapes.

Referring again to FIG. 1, according to some embodiments, a protection plate 250 may be disposed on the bottom portion 220b of the process chamber 220 at a side of the lift plate 237. For example, as illustrated in FIG. 1, the protection plate 250 may be directly on a surface of the bottom portion 220b of the process chamber 220 facing an interior of the process chamber 220. For example, as further illustrated in FIG. 1, the protection plate 250 may be positioned between the lift plate 237 and the wall portion 220w of the process chamber 220, e.g., an edge of the protection plate 250 facing the lift plate 237 may overlap an edge of the substrate 150. The protection plate 250 may be formed of a material having a melting point higher than that of the bottom portion 220b. The protection plate 250 may protect the bottom portion 220b thereunder from the laser beam 265. For example, the bottom portion 220b of the process chamber 220 may be formed of an aluminum alloy, and the protection plate 250 may be formed of ceramic, e.g., aluminum oxide or aluminum nitride.

The bottom portion 220b may include an overlap portion vertically overlapping with the loaded substrate 150 and a non-overlap portion not overlapping with the loaded substrate 150, e.g., only a portion of the bottom portion 220b overlaps the loaded substrate 150. Further, at least a first portion of the protection plate 250 may be disposed in the overlap region between the bottom portion 220b and the loaded substrate 150, so a second portion of the protection plate 250 may be in the non-overlap region between the bottom portion 220b and the loaded substrate 150. Thus, the at least a portion of the protection plate 250 does not vertically overlap with the chuck 230.

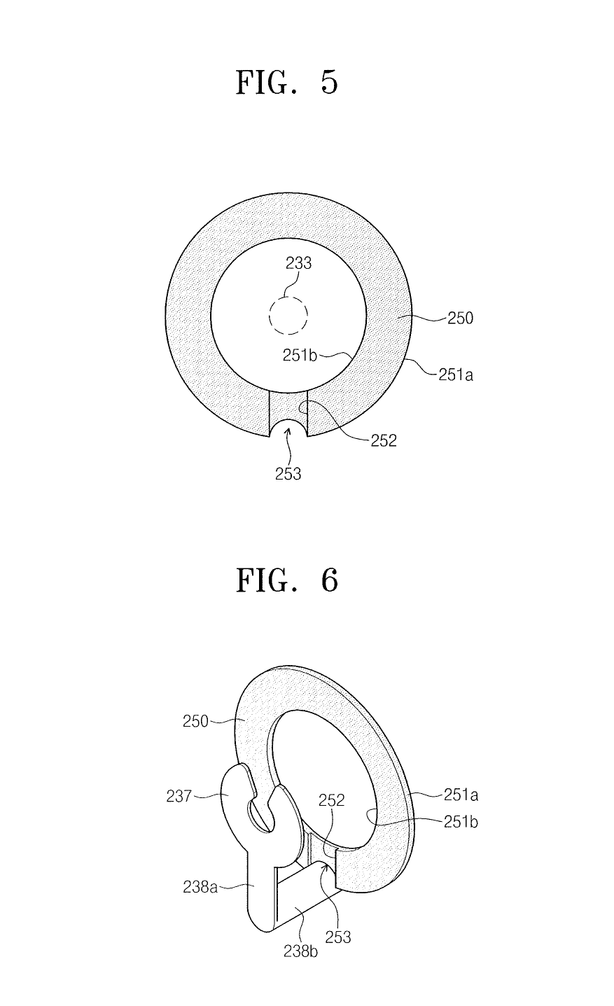

The protection plate 250 according to some will be described in more detail with reference to FIGS. 5 and 6. FIG. 5 illustrates a plan view of the protection plate 250 of the laser annealing apparatus 100. FIG. 6 illustrates a perspective view of the protection plate 250 of the laser annealing apparatus 100.

As illustrated in FIG. 5, the protection plate 250 may have a ring shape, e.g., a doughnut shape, that surrounds the chuck supporter 233 when viewed from a plan view, e.g., the protection plate 250 and the chuck supporter 233 may be concentric. The protection plate 250 may be, e.g., radially, spaced apart from the chuck supporter 233.

Referring to FIGS. 1, 5, and 6, the protection plate 250 having the ring shape may have an outer sidewall 251a and an inner sidewall 251b opposite to the outer sidewall 251a. In an embodiment, a portion of the outer sidewall 251a of the protection plate 250 may have a concave region 253 toward the inner sidewall 251b. In an embodiment, the protection plate 250 may include a groove 252 that extends from the inner sidewall 251b to the outer sidewall 251a. The concave region 253 may be formed at one end of the groove 252 which is adjacent to the outer sidewall 251a. The lift plate 237 may be disposed between the protection plate 250 and the chuck supporter 233 when viewed from a plan view. In an embodiment, the lift plate 237 may be fixed to a first end of a lift arm 238a, and a second end of the lift arm 238a may be fixed to a top end of a shaft 238b. The shaft 238b may be vertically moved, so the lift plate 237 may be vertically moved along the sidewall of the chuck supporter 233. In an embodiment, the shaft 238b may have a cylindrical shape.

As illustrated in FIG. 6, the shaft 238b may be installed in the concave region 253 of the protection plate 250. If the lift plate 237 descends by the shaft 238b, a portion of the lift arm 238a may be delivered safely in the groove 252 of the protection plate 250. The concave region 253 and the groove 252 of the protection plate 250 may correspond to spaces that receive the shaft 238b and the lift arm 238a to vertically move the lift plate 233. In an embodiment, the shapes and sizes, e.g., widths, of the concave region 253 and the groove 252 of the protection plate 250 may be varied according to the shapes and sizes of the shaft 238b and the lift arm 238a, respectively. However, embodiments are not limited to the shape of the protection plate 250 illustrated in FIGS. 5 and 6. In other words, the shape of the protection plate 250 may be variously modified.

Next, a method of operating the laser annealing apparatus 100 will be described with reference to FIGS. 7, 8, and 1.

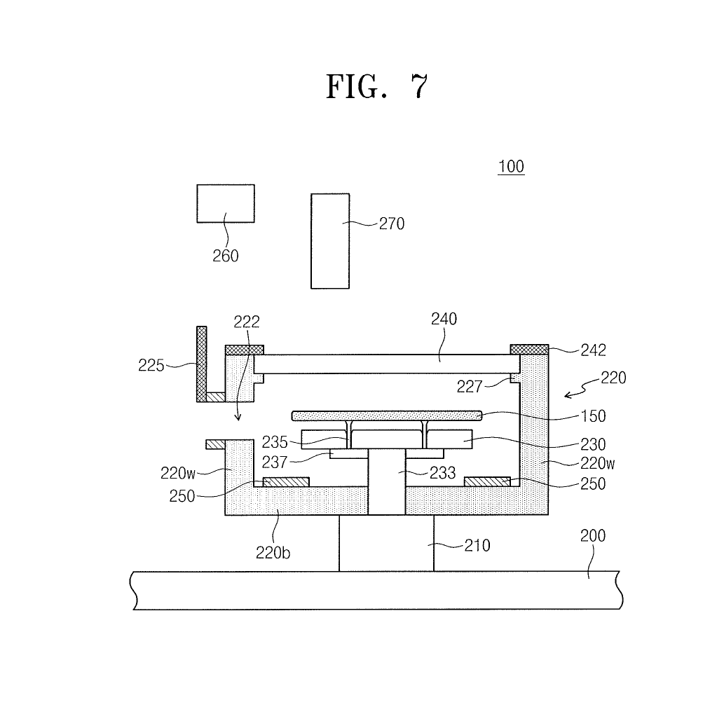

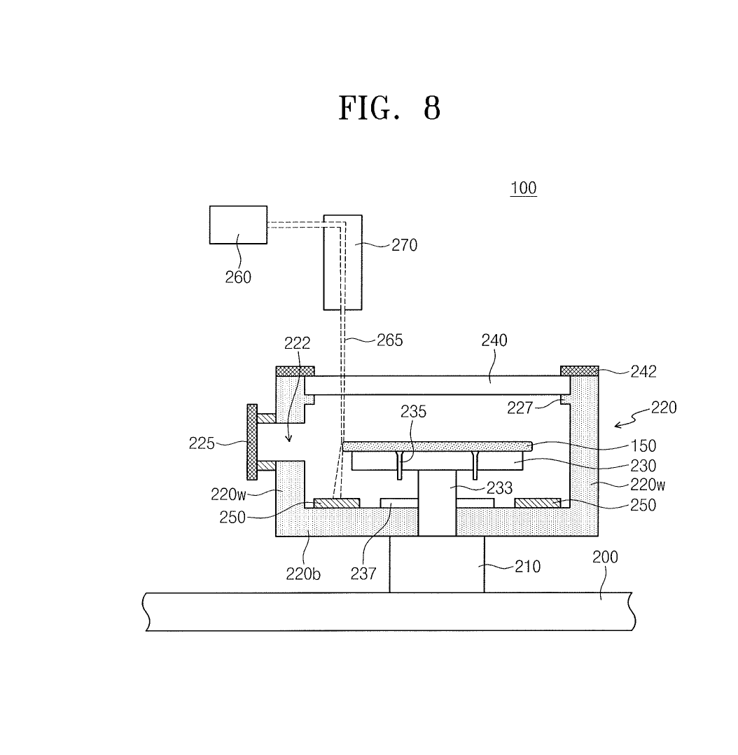

FIGS. 7 and 8 illustrate cross-sectional views of stages in a method of operating the laser annealing apparatus illustrated in FIG. 1.

Referring to FIG. 7, first, the lift plate 237 may be moved upward along the sidewall of the chuck supporter 233 to lift the lift pins 235. Thus, the head portion of the lift pin 235 may protrude above the top surface of the chuck 230. The door unit 225 may open the substrate path 222, and the substrate 150 may be then transferred into the process chamber 220 through the open substrate path 222. The transferred substrate 150 may be loaded on the lift pins 235 lifted by the lift plate 233. In an embodiment, the lift plate 237 may be moved by the lift arm 238a and the shaft 238b illustrated in FIG. 6.

Referring again to FIG. 1, the door unit 225 may close the substrate path 222. The lift plate 233 may be moved downward, so the lift pins 235 may descend. Thus, the substrate 150 may be loaded on the top surface of the chuck 230. The chuck 230 may fix the loaded substrate 150 by an electrostatic force or by vacuum pressure. In an embodiment, if the chuck 230 performs the heater function, the loaded substrate 150 may be heated to a predetermined temperature by the chuck 230.

Next, as illustrated in FIG. 8, the laser source 260 may generate the laser beam 265, and the laser beam 265 may be irradiated toward the top surface of the loaded substrate 150 through the beam delivery optic structure 270 and through the chamber window 240. In an embodiment, the chamber supporter 210 and the process chamber 220 may be two-dimensionally moved on the stage 200, so the laser beam 265 may be irradiated to an entire top surface of the loaded substrate 150. However, embodiments are not limited thereto. In another embodiment, the process chamber 220 may be fixed, and the laser source 260 and the beam delivery optic structure 270 may be moved to irradiate the laser beam 265 to the entire top surface of the loaded substrate 150.

As further illustrated in FIG. 8, since the width W2 of the chuck 230 is smaller than the width W1 of the loaded substrate 150 as described above, the loaded substrate 150 completely covers the chuck 230. That is, the loaded substrate 150 may extend beyond, e.g., an outermost edge of, the chuck 230 along an entire perimeter of the chuck 230. As a result, even though the laser beam 265 is irradiated toward the edge portion of the loaded substrate 150, the laser beam 265 does not reach the chuck 230. Therefore, it is possible to prevent the chuck 230 from being damaged by the laser beam 265.

In general, if a width of a chuck were to be greater than that of a loaded substrate, an edge of the chuck would not be covered by the loaded substrate but would be exposed. In this case, a laser beam could be irradiated toward an edge of the chuck during irradiation toward an edge of the loaded substrate. Thus, the edge of the chuck would be damaged by the laser beam to cause contamination sources. For example, when the chuck is formed of metal, e.g., aluminum, metal contamination sources could occur upon laser irradiation of the edge of the chuck, thereby causing defects and/or failures of semiconductor devices formed on the substrate.

In contrast, according to embodiments, since the width W2 of the chuck 230 is smaller than the width W1 of the loaded substrate 150, the chuck 230 is completely covered by the loaded substrate 150 and is not exposed to the laser beam 265. As a result, generation of contamination sources during laser irradiation, and in turn damage to the chuck, may be prevented or substantially minimized.

In an embodiment, when the laser beam 265 is irradiated toward the edge portion of the loaded substrate 150, as illustrated in FIG. 8, a portion of the laser beam 265 may be irradiated outside the loaded substrate 150, i.e., toward a portion of the bottom portion 220b of the process chamber 220. In this case, since the bottom portion 220b is disposed at a lower level than the loaded substrate 150, the laser beam 265 may defocus on the top surface of the bottom portion 220b. Thus, an intensity of the laser beam 265 on the top surface of the bottom portion 220b may be smaller than an intensity of the laser beam 265 on the top surface of the loaded substrate 150. In other words, even though the portion of the laser beam 265 may be irradiated toward the bottom portion 220b during irradiation toward the edge portion of the loaded substrate 150, damage to the bottom portion 220b may be minimized due to the focusing of the laser.

In addition, according to some embodiments, the protection plate 250 may be disposed on the bottom portion 220b, as illustrated in FIGS. 1 and 8. Thus, the portion of the laser beam 265 irradiated outside of the loaded substrate 150, i.e., toward the bottom portion 220b, may be incident on the protection plate 250. In other words, the bottom portion 220b may be protected by the protection plate 250. Since the melting point of the protection plate 250 is higher than that of the bottom portion 220b, as described above, the protection plate 250 may effectively protect the bottom portion 220b and may prevent generation of contamination sources.

After the laser annealing process is completed, the substrate 150 may be lifted by the lift plate 237 and the lift pins 235. The door unit 225 may open the substrate path 222, so the substrate 150 may be unloaded from the process chamber 220 through the substrate path 222.

Next, other embodiments will be described. Hereinafter, the same elements as described in the above embodiment will be indicated by the same reference numerals or the same reference designators. For the purpose of ease and convenience, descriptions of the same elements as in the above embodiment will be omitted or mentioned briefly. In other words, only differences between the above embodiment and other embodiments will be described in detail.

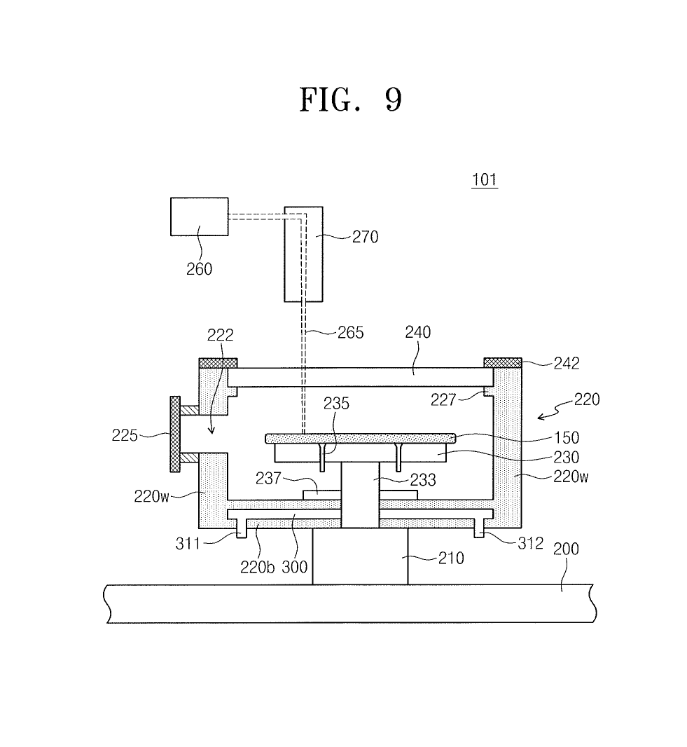

FIG. 9 illustrates a cross-sectional view of a laser annealing apparatus according to other embodiments.

Referring to FIG. 9, in a laser annealing apparatus 101 according to the present embodiment, a cooling channel 300, through which a coolant flows, may be formed within the bottom portion 220b of the process chamber 220. For example, the coolant may be water. The bottom portion 220b of the process chamber 220 may be cooled by the coolant flowing through the cooling channel 300. Thus, even though the laser beam 265 is irradiated to the bottom portion 220b, damage of the bottom portion 220b may be minimized.

In an embodiment, the bottom portion 220b of the process chamber 220 may include an overlap portion vertically overlapping with the loaded substrate 150 and a non-overlap portion not overlapping with the loaded substrate 150. At least a portion of the cooling channel 300 may vertically overlap with the non-overlap portion adjacent to the overlap portion. In other words, at least a portion of the cooling channel 300 may vertically overlap with a portion of the bottom portion 220b to which the laser beam 265 is irradiated. Thus, the coolant may effectively cool the portion of the bottom portion 220b to which the laser beam 265 is irradiated.

An inlet 311 may be connected to a first portion of the cooling channel 300, and an outlet 312 may be connected to a second portion of the cooling channel 300. The coolant may be supplied into the cooling channel 300 through the inlet 311, and may be exhausted from the cooling channel 300 through the outlet 312. In other words, the coolant may be circulated through the inlet 311, the cooling channel 300, and the outlet 312.

In the present embodiment, the protection plate 250 of FIG. 1 may be omitted. However, embodiments are not limited thereto. In another embodiment, the laser annealing apparatus 101 according to the present embodiment may further include the protection plate 250 of FIG. 1.

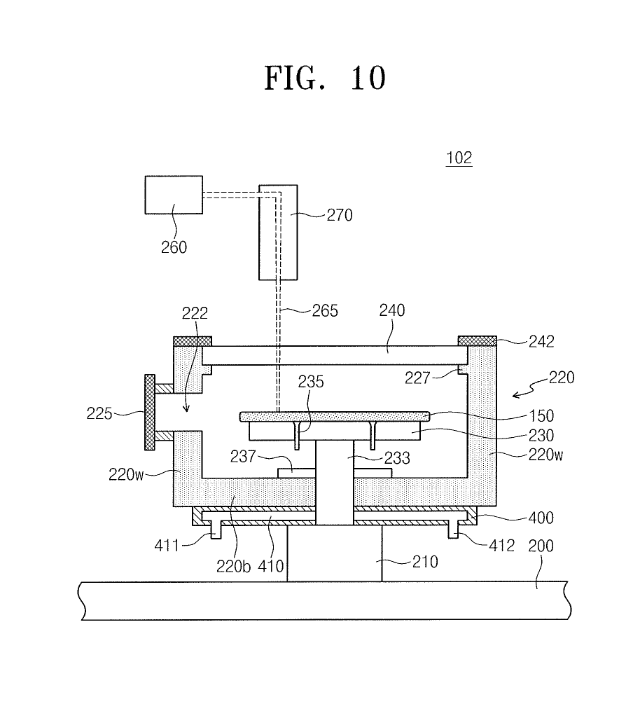

FIG. 10 illustrates a cross-sectional view of a laser annealing apparatus according to still other embodiments.

Referring to FIG. 10, a laser annealing apparatus 102 according to the present embodiment may include a cooling plate 400 that is disposed under the bottom portion 220b of the process chamber 220. The cooling plate 400 may be disposed between the bottom portion 220b of the process chamber 200 and the chamber supporter 210. In an embodiment, the cooling plate 400 may be in contact with a bottom surface of the bottom portion 220b. In an embodiment, the chuck supporter 233 may penetrate the cooling plate 400 so as to be connected to the chamber supporter 210. The cooling plate 400 may cool the bottom portion 220b of the process chamber 220 during the laser annealing process. Thus, even though a portion of the laser beam 265 is irradiated to the bottom portion 220b during the laser annealing process, damage to the bottom portion 220b may be minimized or prevented.

In an embodiment, the bottom portion 220b of the process chamber 220 may include an overlap portion vertically overlapping with the loaded substrate 150 and a non-overlap portion not overlapping with the loaded substrate 150. At least a portion of the cooling plate 400 may vertically overlap with the non-overlap portion adjacent to the overlap portion. In other words, the at least a portion of the cooling plate 400 may vertically overlap with a portion of the bottom portion 220b to which the laser beam 265 is irradiated. Thus, the cooling plate 400 may effectively cool the portion of the bottom portion 220b to which the laser beam 265 is irradiated.

In an embodiment, the cooling plate 400 may include a cooling channel 410 through which a coolant flows. In other words, the cooling channel 410 may be formed within the cooling plate 400. In an embodiment, at least a portion of the cooling channel 410 of the cooling plate 400 may vertically overlap with the non-overlap portion of the bottom portion 220b. In other words, the at least portion of the cooling channel 410 may vertically overlap with the portion of the bottom portion 220b to which the laser beam 265 is irradiated. The coolant flowing through the cooling channel 410 may be, for example, water. An inlet 411 and an outlet 412 may be connected to a first portion and a second portion of the cooling channel 410, respectively. The coolant may be circulated through the inlet 411, the cooling channel 410, and the outlet 412.

In the present embodiment, the protection plate 250 of FIG. 1 and the cooling channel 300 disposed in the bottom portion 220b of FIG. 9 may be omitted. However, embodiments are not limited thereto. In other embodiments, the laser annealing apparatus 102 according to the present embodiment may further include the protection plate 250 of FIG. 1 and/or the cooling channel 300 of FIG. 9.

As described above, the width of the chuck may be smaller than the width of the substrate loaded on the chuck in the laser annealing apparatus, and thus, the chuck may be completely covered and protected by the loaded substrate during the laser annealing process. Further, a compensation plate may be positioned under the chuck to contact a bottom of the process chamber. e.g., a protection plate or a cooling channel, to protect the bottom of the process chamber from high laser temperature. Accordingly, damage to the chuck or process chamber may be prevented or substantially minimized. As a result, generation of contamination sources may be minimized or prevented, and the reliability of the laser annealing process may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A laser annealing apparatus, comprising:
a process chamber including a chamber window to transmit a laser beam; and
a chuck in the process chamber, a top surface of the chuck supporting a loaded substrate, and a width of the chuck being smaller than a width of the loaded substrate.

2. The laser annealing apparatus as claimed in claim 1, wherein a bottom surface of an edge portion of the loaded substrate on the chuck is exposed.

3. The laser annealing apparatus as claimed in claim 1, wherein an area of the loaded substrate is greater than an area of the top surface of the chuck, the chuck being completely covered by the loaded substrate.

4. The laser annealing apparatus as claimed in claim 1, wherein the width of the chuck is smaller than 100% of the width of the loaded substrate and is equal to or greater than 80% of the width of the loaded substrate.

5. The laser annealing apparatus as claimed in claim 1, further comprising a laser source to generate the laser beam,
wherein the process chamber further comprises:
a bottom portion on which the chuck is disposed, and
a wall portion extending upward from an edge of the bottom portion,
wherein the chamber window closes a top end of an inner space surrounded by the bottom portion and the wall portion, and
wherein the laser beam is irradiated toward the loaded substrate through the chamber window.

6. The laser annealing apparatus as claimed in claim 5, further comprising a protection plate disposed on the bottom portion of the process chamber,
wherein the protection plate is formed of a material having a melting point higher than that of the bottom portion of the process chamber,
wherein the bottom portion of the process chamber includes:
an overlap portion vertically overlapping with the loaded substrate, and
a non-overlap portion not overlapping with the loaded substrate, and
wherein at least a portion of the protection plate is on the non-overlap portion adjacent to the overlap portion.

7. The laser annealing apparatus as claimed in claim 6, further comprising a chuck supporter under the chuck and supporting the chuck,
wherein a width of the chuck supporter is smaller than the width of the chuck, and
wherein the protection plate has a ring shape that surrounds the chuck supporter when viewed from a plan view.

8. The laser annealing apparatus as claimed in claim 7, wherein a portion of an outer sidewall of the protection plate is concave toward an inner sidewall of the protection plate.

9. The laser annealing apparatus as claimed in claim 5, further comprising a cooling channel within the bottom portion of the process chamber, a coolant flowing through the cooling channel.

10. The laser annealing apparatus as claimed in claim 5, further comprising a cooling plate under the bottom portion of the process chamber.

11. The laser annealing apparatus as claimed in claim 10, wherein the cooling plate includes a cooling channel to accommodate a coolant flow,
wherein the bottom portion of the process chamber includes:
an overlap portion vertically overlapping with the loaded substrate, and
a non-overlap portion not overlapping with the loaded substrate, and
wherein at least a portion of the cooling plate vertically overlaps with the non-overlap portion adjacent to the overlap portion.

12. A laser annealing apparatus, comprising:
a process chamber including a bottom portion, a wall portion extending upward from an edge of the bottom portion, and a chamber window closing a top end of an inner space surrounded by the bottom portion and the wall portion;
a chuck on the bottom portion of the process chamber, the chuck having a top surface on which a substrate is loaded; and
a laser source to generate a laser beam irradiated toward the loaded substrate through the chamber window,
wherein a width of the chuck is smaller than a width of the loaded substrate, and
wherein a bottom surface of an edge portion of the substrate loaded on the chuck is exposed.

13. The laser annealing apparatus as claimed in claim 12, further comprising:
a protection plate disposed on the bottom portion of the process chamber,
wherein the protection plate is formed of a material having a melting point higher than that of the bottom portion of the process chamber,
wherein at least a portion of the protection plate does not vertically overlap with the loaded substrate, and
wherein a portion of the laser beam is irradiated to the at least portion of the protection plate when the laser beam is irradiated to the edge portion of the loaded substrate.

14. The laser annealing apparatus as claimed in claim 13, further comprising a cooling channel within the bottom portion of the process chamber.

15. The laser annealing apparatus as claimed in claim 13, further comprising a cooling plate in contact with a bottom surface of the bottom portion of the process chamber.

16. A laser annealing apparatus, comprising:
a process chamber including a chamber window to transmit a laser beam;
a chuck on a bottom of the process chamber; and
a compensation plate contacting the bottom of the process chamber and having an outermost edge adjacent to a sidewall of the process chamber, at least a portion of the compensation plate overlapping the chuck.

17. The laser annealing apparatus as claimed in claim 16, wherein the compensation plate is a protection plate having a melting point higher than that of the bottom of the process chamber.

18. The laser annealing apparatus as claimed in claim 17, wherein the protection plate is between the bottom of the process chamber and the chuck, the protection plate extending along an entire perimeter of the chuck and having an outermost edge closer to the sidewall of the process chamber than to an outermost edge of the chuck.

19. The laser annealing apparatus as claimed in claim 16, wherein the compensation plate includes a cooling channel within the bottom of the process chamber.

20. The laser annealing apparatus as claimed in claim 16, wherein the compensation plate includes a cooling channel under the bottom of the process chamber, the bottom of the process chamber being between the cooling channel and the chuck.
